(19) United States
(12) Patent Application Publication
(10) Pub. No.: US 2008/0129317 A1
(43) Pub. Date: Jun. 5, 2008

(54) INPUT DEVICE AND METHOD OF MANUFACTURING THE SAME

(76) Inventor: Katsuichi Oba, Fukushima-ken (JP)

Correspondence Address: BRINKS HOFER GILSON & LIONE, P.O. BOX 10395, CHICAGO, IL, 60610, US

(21) Appl. No.: 11/945,836

(22) Filed: Nov. 27, 2007

(30) Foreign Application Priority Data
Dec. 1, 2006 (JP) 2006-325611

(51) Int. Cl. G01R 27/26; H01L 21/02

(52) U.S. Cl. 324/663; 438/50; 257/E21.008

(57) ABSTRACT

An input device is disclosed that includes a shield layer for reducing the influence of radiation noise and has a low manufacturing cost and a stable operation and a method of manufacturing the input device. A method of manufacturing a touch sensor includes: forming conductive films and on front and rear surfaces of a transparent base substrate, respectively; radiating a laser beam onto the conductive films to form partitioning grooves, thereby forming a plurality of electrodes on both the conductive films at the same time; sequentially forming an insulating layer, wiring patterns, and a protective layer on one of the conductive films; forming a conductive pattern on the other of the conductive films to electrically connect the electrodes such that the conductive pattern and the electrodes serve as the ground; and forming a sensitivity adjusting layer with a predetermined thickness on the conductive pattern and the electrodes.

### CLAIM OF PRIORITY

This application claims benefit of the Japanese Patent Application No. 2006-325611 filed on Dec. 1, 2006, the entire content of which is hereby incorporated by reference.

### BACKGROUND

1. Field of the Invention

The present invention relates to a method of manufacturing a capacitive input device that detects a variation in capacitance using plane electrodes when an operating body, such as a finger, approaches or comes into contact with the electrodes, and more particularly, to an input device including a shield layer for reducing the influence of radiation noise generated from the inside of an electronic apparatus and to a method of manufacturing the same.

2. Description of the Related Art

JP-T-2003-511799 discloses a transparent capacitive sensor. For example, as shown in FIG. 6 of JP-T-2003-511799, the sensor includes a transparent X conductor trace formed on a front surface of a transparent insulator and a Y conductor trace formed on a rear surface of the insulator. In addition, a transparent conductor, which is a solid layer, is formed on a lower surface of the sensor. In the sensor, the conductor is connected to the ground to isolate the sensor from electric noise generated from an electric circuit (for example, a display device) that is provided at a lower part.

In general, an electronic apparatus varies a voltage or current in order to transmit signals. When a voltage or current varies, electromagnetic waves (radiation noise) are generated from transmission lines. When a large amount of radiation noise is generated, the sensor close to the transmission lines is greatly affected by the radiation noise, which causes the accuracy of the sensor to be lowered. Therefore, preferably, a shield layer formed of a transparent conductor that is connected to the ground is provided between the sensor and the electric circuit in order to reduce the influence of the radiation noise on the sensor.

However, in a method of manufacturing the sensor disclosed in JP-T-2003-511799, first, the X and Y conductor traces are separately formed on two transparent base substrates, and the two transparent base substrates are bonded to each other with an insulator interposed therebetween, which makes it difficult to reduce a manufacturing cost.

### SUMMARY

In an embodiment, a capacitive input device using plane electrodes is disclosed that can operate stably and a method of manufacturing the input device.

According to an aspect of the disclosure, an input device includes: a base substrate; conductive films that are formed on front and rear surfaces of the base substrate; a plurality of electrodes that are formed on the front surface of the base substrate and are partitioned in a predetermined shape by a plurality of partitioning grooves The electrodes serve as sensing units for detecting a variation in capacitance between an operating body and the electrodes. A plurality of electrodes are formed on the rear surface of the base substrate in the same shape and the same array as those of the electrodes formed on the front surface such that they are electrically connected to each other.

According to the above-mentioned structure, the electrodes formed on the front surface of the base substrate and the electrodes formed on the rear surface of the base substrate have the same shape and the same array. Therefore, it is possible to set the capacitance C of each of the sensing units composed of the electrodes to be equal to or greater than a predetermined value, and thus achieve a touch sensor having high stability.

According to another aspect of the invention, there is provided a method of manufacturing an input device including sensing units that detect a variation in capacitance between an operating body and the sensing units. The method includes: forming conductive films on front and rear surfaces of a base substrate; radiating a laser beam onto the conductive films to form partitioning grooves, thereby forming wiring conductive films and electrodes that are partitioned in predetermined shapes by the partitioning grooves on at least one of the conductive films, the electrodes serving as the sensing units; forming an insulating layer on some of the wiring conductive films that are formed on the one conductive film; forming wiring patterns on the insulating layer so as to be electrically connected to the corresponding electrodes; and forming a conductive pattern on the other conductive film so as to electrically connect the electrodes that are partitioned by the partitioning grooves.

According to the above-mentioned aspect, it is possible to reduce the number of manufacturing processes and thus reduce manufacturing costs.

As described above, the disclosed embodiments can provide a stable capacitive input device without being erroneously operated.

Further, according to the capacitive input device according to the disclosed embodiment, it is possible to shorten the time required to manufacture the input device and reduce the number of manufacturing processes, which results in a low manufacturing cost.

### BRIEF DESCRIPTION OF THE DRAWINGS

FIG. 1A is a plan view illustrating a front surface of a touch sensor according to an embodiment;

FIG. 1B is a plan view illustrating a rear surface of the touch sensor according to the embodiment;

FIG. 2 is an enlarged cross-sectional view illustrating a portion of a touch sensor according to a first embodiment;

FIG. 3A is a partial cross-sectional view illustrating a process of a method of manufacturing the touch sensor according to the first embodiment;

FIG. 3B is a partial cross-sectional view illustrating a process subsequent to the process shown in FIG. 3A;

FIG. 3C is a partial cross-sectional view illustrating a process subsequent to the process shown in FIG. 3B;

FIG. 3D is a partial cross-sectional view illustrating a process subsequent to the process shown in FIG. 3C;

FIG. 3E is a partial cross-sectional view illustrating a process subsequent to the process shown in FIG. 3D;

FIG. 3F is a partial cross-sectional view illustrating a process subsequent to the process shown in FIG. 3E;

FIG. 3G is a partial cross-sectional view illustrating a process subsequent to the process shown in FIG. 3F;

FIG. 4 is an enlarged cross-sectional view illustrating a portion of a touch sensor according to a second embodiment;

FIG. 5A is a partial cross-sectional view illustrating a process of a method of manufacturing the touch sensor according to the second embodiment;

FIG. 5B is a partial cross-sectional view illustrating a process subsequent to the process shown in FIG. 5A;

FIG. 5C is a partial cross-sectional view illustrating a process subsequent to the process shown in FIG. 5B;

FIG. 5D is a partial cross-sectional view illustrating a process subsequent to the process shown in FIG. 5C;

FIG. 5E is a partial cross-sectional view illustrating a process subsequent to the process shown in FIG. 5D; and

FIG. 5F is a partial cross-sectional view illustrating a process subsequent to the process shown in FIG. 5E.

### DESCRIPTION OF THE EMBODIMENTS

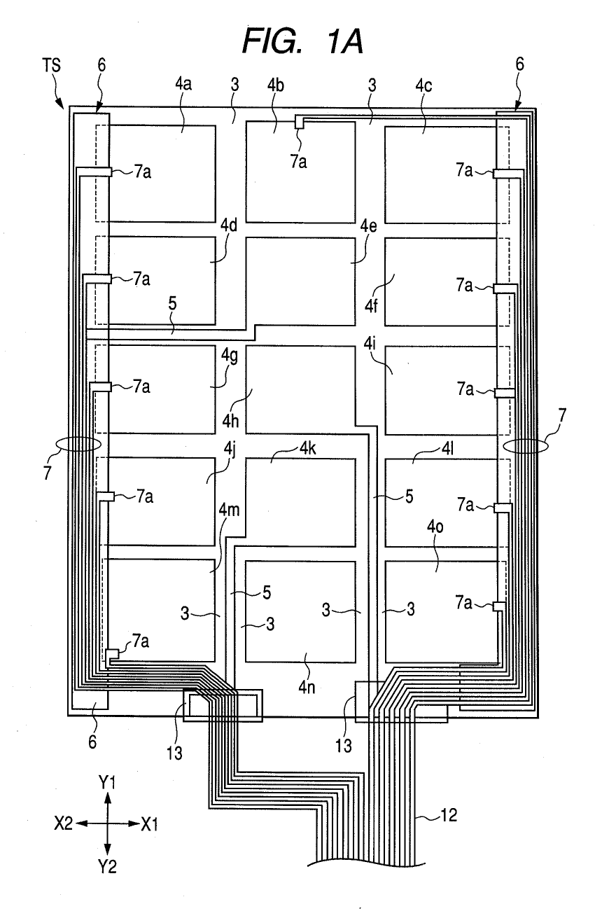

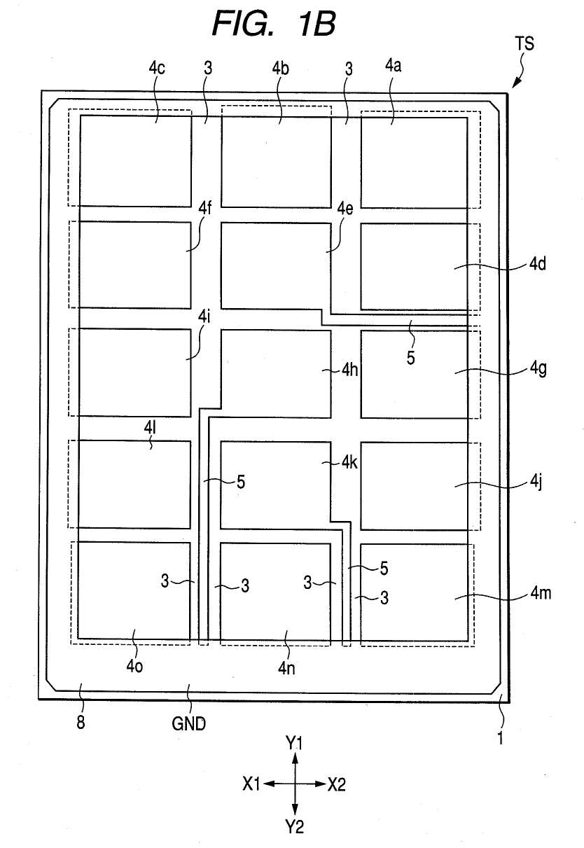

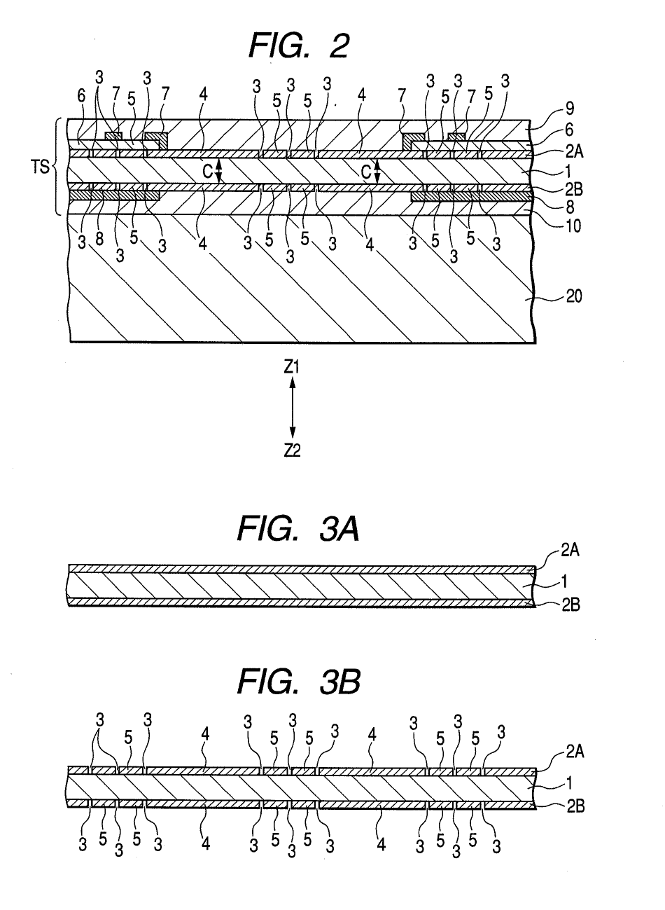

FIGS. 1A and 1B are plan views illustrating a touch sensor (a capacitive input device using plane electrodes) according to an embodiment. Specifically, FIG. 1A is a plan view illustrating a front surface of the touch sensor, and FIG. 1B is a plan view illustrating a rear surface of the touch sensor. FIG. 2 is an enlarged cross-sectional view illustrating a portion of an input device according to a first embodiment. In the drawings, an X-axis direction indicates a horizontal direction, a Y-axis direction indicates a vertical direction, and a Z-axis direction indicates a thickness direction (Z). The X-axis, Y-axis, and Z-axis directions are orthogonal to each other. In the thickness direction (Z), a direction Z1 indicates an upward direction in which an operating body, such as a finger or a pen, is positioned, and a direction Z2 indicates a downward direction in which, for example, a liquid crystal display device 20 is arranged.

A touch sensor (a capacitive input device using plane electrodes) TS according to this embodiment is provided in an electronic apparatus, such as a mobile phone or a PDA, while being laminated on a display device, such as a liquid crystal display device. The touch sensor detects coordinates of an operating body, such as a finger or a pen, on the display device, and transmits input information to a control unit of an electronic apparatus.

As shown in FIGS. 1A, 1B, and 2, the touch sensor TS according to this embodiment includes a base substrate 1, conductive films 2A and 2B, an insulating layer 6, wiring patterns 7, and a flexible cable 12.

The base substrate 1 is formed of a sheet member made of a transparent and insulating material, such as polyethylene terephthalate (PET). It is preferable that the base substrate 1 have plasticity. When the base substrate 1 has plasticity, it is possible to mount the touch sensor TS to a case having a curved surface and thus improve flexibility in mounting the touch sensor TS.

The conductive film 2A is composed of a thin metal film formed of a transparent material, such as ITO, and is formed on an upper surface of the transparent base substrate 1. As shown in FIG. 1A, the conductive film 2A is provided with a plurality of partitioning grooves 3 that have the vertical and horizontal directions as their longitudinal directions, a plurality of electrodes 4 (4a to 4o) that are partitioned by the plurality of partitioning grooves 3 and are arranged in a matrix, and wiring conductive films 5 which are portions other than the electrodes 4a to 4o and each of which is formed between two or more adjacent partitioning grooves 3. Each of the electrodes 4a to 4o is a transparent electrode having a substantially rectangular shape with a predetermined area, and serves as a sensing unit. In addition, each of the electrodes 4a to 4o may have a predetermined area, and the electrodes 4a to 4o may be formed in the same shape and with the same area.

The insulating layer 6 is partially formed between adjacent electrodes 4, that is, on the partitioning grooves 3 or the wiring conductive film 5, at the ends of the conductive film 2A in the directions X1 and X2. A plurality of wiring patterns 7 are formed on the insulating layer 6. One end 7a of each of the wiring patterns 7 is connected to a corresponding one of the electrodes 4a to 4o, and the other ends of the wiring patterns 7 extend to the outside of the touch sensor TS through the flexible cable 12 that is connected to the base substrate 1. A protective layer 9 formed of a transparent resist material covers the conductive film 2A, the insulating layer 6, and the wiring patterns 7, that is, an uppermost layer.

In this embodiment, the conductive film 2B having the same structure as the conductive film 2A is formed on the lower surface of the base substrate 1. That is, the conductive film 2B is composed of a thin metal film formed of a transparent material, such as ITO. The partitioning grooves 3, the electrodes 4, and the wiring conductive films 5 are formed on the conductive film 2B, similar to the conductive film 2A.

As shown in FIG. 1B, a frame-shaped conductive pattern 8 is formed on the rear surface of the base substrate 1 around four sides. The conductive pattern 8 electrically connects the electrodes 4 partitioned by the partitioning grooves 3 and the wiring conductive films 5, so that the same potential is applied to the entire conductive film 2B.

In this embodiment, the conductive film 2B forms the ground GND, and is interposed between the liquid crystal display device 20 and the electrodes 4a to 4o formed in the conductive film 2A. Therefore, the conductive film 2B serves as a shielding layer that reduces the influence of radiation noise generated from the liquid crystal display device 20 on the sensing units. The conductive film 2B may not include the partitioning grooves 3. That is, the lower surface of the base substrate 1 may be covered with one thin metal film (a so-called ‘solid film’).

In the touch sensor TS, a predetermined voltage is applied between each of the electrodes 4a to 4o forming the conductive film 2A and the conductive film 2B forming the ground GND. In this case, capacitance C is formed between each of the electrodes 4a to 4o formed in the conductive film 2A and the conductive film 2B serving as the ground GND.

When an operating body comes into contact with the surface of the protective layer 9, the capacitance C formed between one of the electrodes 4 of the conductive film 2A that faces the operating body and the conductive film 2B, serving as the ground GND, varies. A detecting circuit (not shown) detects the variation in the capacitance C, which makes it possible to calculate the position (the position on the XY plane) of the operating body.

When the operator holds an electronic apparatus provided with the touch sensor TS with hands, an operating body, such as the operator's finger, comes into contact with the rear surface of the touch sensor TS as well as the front surface. In this case, when the distance between the operating body that contacts with the rear surface of the touch sensor TS and the conductive film 2B that is formed on the rear surface of the base substrate 1 is small, unnecessary capacitive coupling is formed between the operating body and the conductive film 2B, which causes the potential of the conductive film 2B (the potential of the ground GND) to vary. As a result, the detection accuracy of the touch sensor TS is likely to be lowered. For this reason, it is preferable that the distance between the conductive film 2B forming the ground GND and the rear surface of the touch sensor TS which comes into contact with the operating body be large (that is, the thickness of the touch sensor TS is large).

Therefore, in this embodiment, a sensitivity adjusting layer 10 made of a transparent resist material is formed on the surface of the conductive film 2B. According to this structure, even when the operator holds the touch sensor TS with operator's hands, little capacitive coupling is formed between the operating body and the conductive film 2B forming the ground GND, which makes it possible to stabilize the potential of the conductive film 2B. As a result, it is possible to improve the detection accuracy of the touch sensor TS.

Next, a method of manufacturing the touch sensor according to the first embodiment of the invention will be described below.

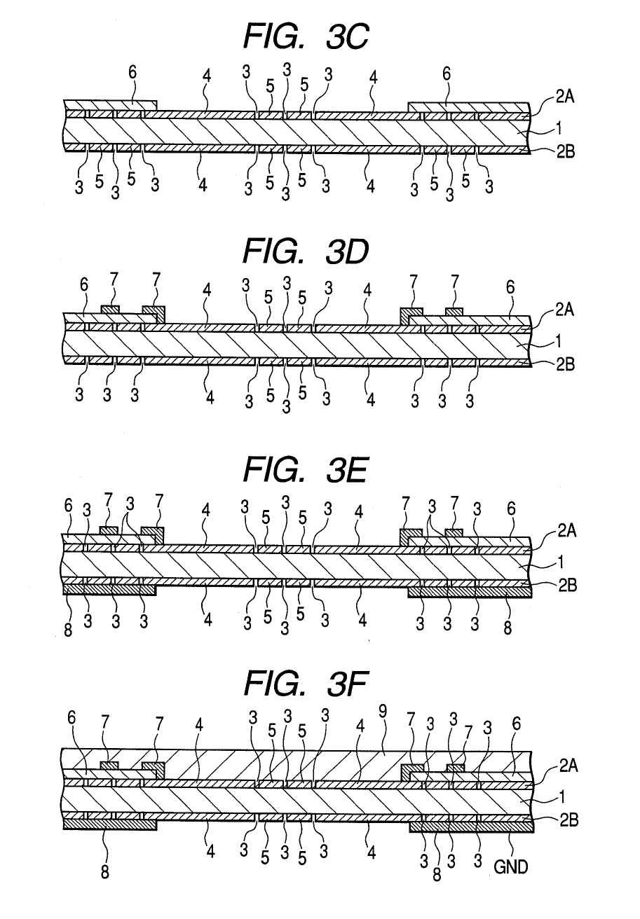

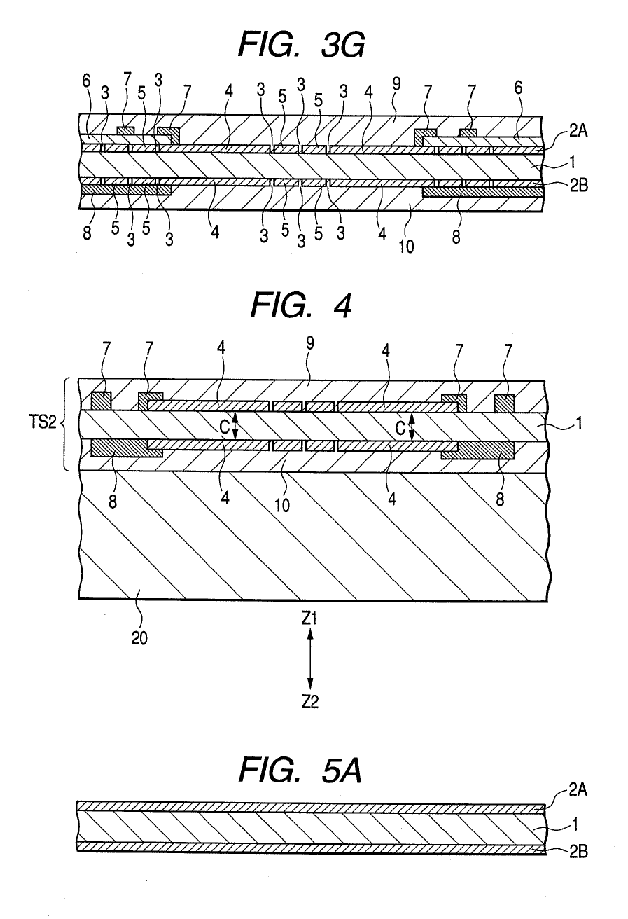

FIGS. 3A to 3G are partial cross-sectional views illustrating a method of manufacturing the touch sensor according to the first embodiment.

As shown in FIG. 3A, in a first process, the base substrate 1 formed of, for example, PET (polyethylene terephthalate) is prepared, and the conductive films 2A and 2B are formed on the front and rear surfaces of the base substrate 1, respectively. The conductive films 2A and 2B are formed of ITO (indium tin oxide). The conductive films 2A and 2B, which are ITO films, are formed on the base substrate 1 by any one of the following methods. First, ITO is deposited on the base substrate 1 in a nitrogen atmosphere by, for example, a vacuum deposition method, and is then heated and oxidized in the atmosphere. Second, a little gas is mixed with Ar gas, which is a discharge gas, a DC glow discharge is generated in the mixed gas atmosphere to generate Ar cations, and the Ar cations collide with an ITO target, thereby forming ITO thin films on the base substrate 1 (sputtering method). Third, a pressure gradient type arc discharge gas is used to perform the evaporation of ITO and the activation of the vapor thereof at the same time, which is called an ion plating method. Alternatively, transparent conductive films that have already been sold at the market may be used as the conductive films 2A and 2B.

As shown in FIG. 3B, in a second process, a plurality of partitioning grooves 3 are formed in both the conductive films 2A and 2B by using a laser apparatus (not shown). A laser beam emitted from the laser apparatus passes through the base substrate 1 from one surface to the other surface. In this embodiment, the laser beam passes through the base substrate 1 from the upper surface of the base substrate 1 toward the conductive film 2A in the direction Z1. The laser beam cuts the conductive film 2A, passes through the base substrate 1 in the thickness direction (Z), and cuts the conductive film 2B formed on the rear surface of the base substrate 1. The laser beam is moved in a predetermined shape in the horizontal and vertical directions on the conductive film 2A to form the plurality of partitioning grooves 3, the electrodes 4 (4a to 4o), and the wiring conductive films 5 shown in FIGS. 1A and 1B on the front and rear surfaces of the base substrate 1 at the same time. That is, the plurality of partitioning grooves 3, the electrodes 4, and the wiring conductive films 5 formed in the conductive film 2A that is formed on the front surface of the base substrate 1 are formed in the same shape and the same array as those of the plurality of partitioning grooves 3, the electrodes 4, and the wiring conductive films 5 formed in the conductive film 2B that is formed on the rear surface of the base substrate 1. The shapes of the components formed in the two conductive films 2A and 2B overlap each other in the thickness direction of the base substrate 1. As described above, in this embodiment, since the electrodes 4 that overlap each other in the thickness direction (Z) are formed in the same shape and the same array, it is possible to set the capacitance C formed between the conductive film 2A and the conductive film 2B to be equal to or greater than a predetermined value. As a result, it is possible to achieve a stable touch sensor TS.

In a third process, as shown in FIG. 3C, for example, an insulating resist material is formed on the conductive film 2A by, for example, a screen printing method, thereby forming the insulating layer 6. In this embodiment, the insulating layer 6 is printed around the edge of the base substrate 1.

In a fourth process, as shown in FIG. 3D, the wiring patterns 7 are formed on the insulating layer 6 by using, for example, an Ag ink. In this case, one end 7a of each of the wiring patterns 7 is connected to a corresponding one of the electrodes 4a to 4o. In addition, the other ends of the wiring patterns 7 extend on the insulating layer 6 to be connected to a connector 13 for connection to the flexible cable 12 that is provided on the base substrate 1.

In a fifth process, as shown in FIG. 3E, for example, an Ag ink is printed on the conductive film 2B formed on the rear surface of the base substrate 1, thereby forming the conductive pattern 8 for the ground GND. The plurality of electrodes 4a to 4o partitioned by the partitioning grooves 3 and the wiring conductive films 5 are electrically connected to each other by the conductive pattern 8. That is, all of the components on the conductive film 2B are electrically connected to each other and serve as the ground GND.

An operable touch sensor TS is manufactured by the first to fifth processes. However, the wiring patterns 7 are exposed from the front surface of the touch sensor TS, and the conductive pattern 8 for the ground GND is exposed from the rear surface of the touch sensor TS. Therefore, a short circuit is likely to occur between the wiring patterns, or dust is likely to be adhered to the wiring patterns, which may cause the deterioration of quality. In order to solve these problems, the following processes are additionally performed.

In a sixth process, as shown in FIG. 3F, a transparent resist material having an insulating property is printed on an uppermost layer to form the protective layer 9.

Then, in a seventh process, as shown in FIG. 3G, a transparent resist material having an insulating property is printed with a predetermined thickness on a lowermost layer to form the sensitivity adjusting layer 10. In this way, the touch sensor TS is completely manufactured. Since the sensitivity adjusting layer 10 is formed with a predetermined thickness, it is possible to set the distance between the operating body that comes into contact with the rear surface of an electronic apparatus provided with the touch sensor TS and the conductive pattern 8 for the ground GND such that there is no variation in the potential of the conductive pattern 8. In this way, it is possible to reduce the erroneous operation of the touch sensor TS and thus improve the detection accuracy of the touch sensor TS.

As described above, according to the method of manufacturing the touch sensor according to the first embodiment, it is possible to effectively manufacture a touch sensor having a high degree of detection accuracy without being erroneously operated.

That is, in the related art, in a first process, a conductive film is formed on one surface of a first base substrate. In a second process, a conductive film is formed on a second base substrate. In a third process, the first base substrate and the second base substrate are bonded to each other. In a fourth process, etching is performed on the conductive film formed on the first base substrate to form partitioning grooves 3, electrodes 4a to 4o, and wiring conductive films 5.

However, according to this embodiment, in the first process, the first and third processes according to the related art are performed at the same time, and a laser is used in the second process, which makes it possible to simultaneously form the partitioning grooves 3, the electrodes 4a to 4o, and the wiring conductive films 5 on both the conductive film 2A and the conductive film 2B. Therefore, the manufacturing method according to this embodiment can considerably reduce the number of manufacturing processes. As a result, according to the manufacturing method of this embodiment, it is possible to shorten the time required to manufacture the touch sensor and reduce manufacturing costs.

In the method of manufacturing the touch sensor according to the first embodiment of the invention, the wiring patterns 7 are formed on the insulating layer 6 (the fourth process shown in FIG. 3D), and then the conductive pattern 8 is formed on the conductive film 2B (the fifth process shown in FIG. 3E). However, the invention is not limited thereto. The order of the fourth and fifth processes may be reversed. That is, first, the conductive pattern 8 may be formed on the conductive film 2B (the fifth process), and then the wiring patterns 7 may be formed on the insulating layer 6 (the fourth process).

Alternatively, after the conductive films 2A and 2B are formed (the second process), the conductive pattern 8 may be formed on the conductive film 2B (the fifth process), the insulating layer 6 may be formed on the conductive film 2A (the third process), and then the wiring patterns 7 may be formed on the insulating layer 6 (the fourth process).

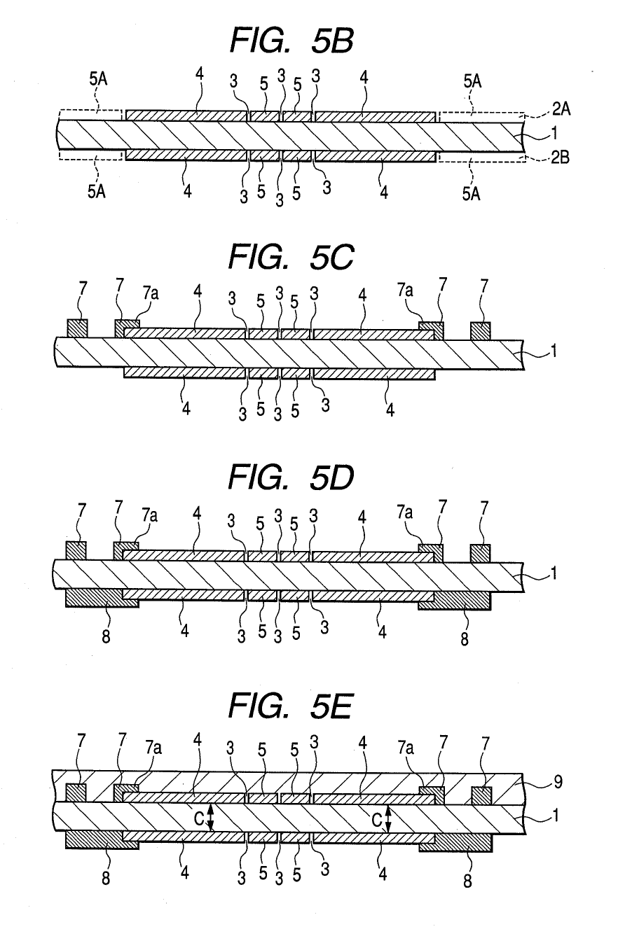

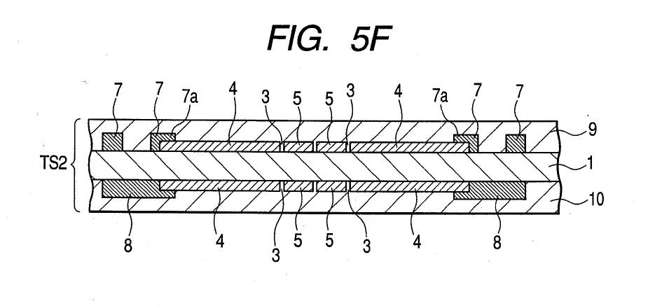

FIG. 4 is an enlarged cross-sectional view illustrating a portion of an input device (a touch sensor) according to a second embodiment of the invention. FIGS. 5A to 5F are partial cross-sectional views illustrating a method of manufacturing the touch sensor according to the second embodiment of the invention. In the second embodiment, the same components as those in the first embodiment are denoted by the same reference numerals.

A touch sensor TS2 (see FIG. 4) according to the second embodiment is similar to the touch sensor TS (see FIG. 2) according to the first embodiment except that the touch sensor TS2 is not provided with the insulating layer 6.

Next, a method of manufacturing the touch sensor TS2 according to the second embodiment (a second manufacturing method) will be described with reference to FIGS. 5A to 5F.

As shown in FIG. 5A, in a first process, a base substrate 1 formed of, for example, PET (polyethylene terephthalate) is prepared, and conductive films 2A and 2B are formed on the front and rear surfaces of the base substrate 1, respectively, similar to the first embodiment.

As shown in FIG. 5B, in a second process, a plurality of partitioning grooves 3 are formed in the conductive films 2A and 2B by using a laser apparatus (not shown), similar to the first embodiment. In this way, a plurality of electrodes 4 (4a to 4o) and wiring conductive films 5 are formed in the same shape and the same array on both the front and rear surfaces of the base substrate 1. However, the second embodiment differs from the first embodiment in that, among the wiring conductive patterns 5, wiring conductive patterns 5A that are disposed at both sides of each of the electrodes 4 (4a to 4o) and are represented by dashed lines in FIG. 5B are removed, so that the base substrate 1 is exposed.

In a third process, as shown in FIG. 5C, wiring patterns 7 are formed on the base substrate 1 by printing, for example, an Ag ink. In this case, one end 7a of each of the wiring patterns 7 is connected to a corresponding one of the electrodes 4a to 4o. In addition, the other ends of the wiring patterns 7 extend on the front surface of the base substrate 1 so as to be connected to a connector 13 (not shown) for connection to a flexible cable 12 that is provided on the base substrate 1, similar to the first embodiment.

In a fourth process, as shown in FIG. 5D, for example, an Ag ink is printed on the rear surface of the base substrate 1 to form a conductive pattern 8 for the ground GND. In this way, on the rear surface of the base substrate 1, a plurality of electrodes 4a to 4o partitioned by the partitioning grooves 3 and the wiring conductive films 5 are electrically connected to each other by the conductive pattern 8. That is, all of the components on the conductive film 2B are electrically connected to each other and serve as the ground GND.

In a fifth process, as shown in FIG. 5E, similar to the first embodiment, a transparent resist material having an insulating property is printed on an uppermost layer to form a protective layer 9. Then, in a sixth process, as shown in FIG. 5F, a transparent resist material having an insulating property is printed with a predetermined thickness on a lowermost layer to form a sensitivity adjusting layer 10. In this way, the touch sensor TS2 is completely manufactured.

Since the sensitivity adjusting layer 10 is formed with a predetermined thickness, it is possible to set the distance between an operating body that comes into contact with the rear surface of an electronic apparatus provided with the touch sensor TS2 and the conductive pattern 8 for the ground GND such that there is no variation in the potential of the conductive pattern 8. In this way, it is possible to reduce the erroneous operation of the touch sensor TS2 and thus improve the detection accuracy of the touch sensor TS2.

Since the touch sensor TS2 according to the second embodiment is not provided with the insulating layer 6, the thickness thereof is reduced by a value corresponding to the insulating layer 6, as compared to the touch sensor TS according to the first embodiment. In addition, in the method of manufacturing the touch sensor according to the second embodiment, it is not necessary to perform a process of forming the insulating layer 6, unlike the first embodiment. As a result, according to the second embodiment, it is possible to reduce manufacturing costs, as compared to the first embodiment.

1. An input device comprising:
a base substrate;
conductive films disposed on front and rear surfaces of the base substrate;
a plurality of electrodes disposed on the front surface of the base substrate and partitioned in predetermined shapes by a plurality of partitioning grooves, the electrodes serving as sensing units that detect a variation in capacitance between an operating body and the electrodes; and
a plurality of electrodes disposed on the rear surface of the base substrate in the same shape and the same array as those of the electrodes formed on the front surface such that they are electrically connected to each other.

2. A method of manufacturing an input device including sensing units that detects a variation in capacitance between an operating body and the sensing units, the method comprising:
forming conductive films on front and rear surfaces of a base substrate;
radiating a laser beam onto the conductive films to form partitioning grooves, thereby forming wiring conductive films and electrodes that are partitioned in predetermined shapes by the partitioning grooves on at least one of the conductive films, the electrodes serving as the sensing units;
forming an insulating layer on some of the wiring conductive films that are formed on the one conductive film;
forming wiring patterns on the insulating layer so as to be electrically connected to the corresponding electrodes; and
forming a conductive pattern on the other conductive film so as to electrically connect the electrodes that are partitioned by the partitioning grooves.

3. The method of manufacturing an input device according to claim 2, further comprising:
covering the one conductive film with a transparent insulating layer after forming the conductive pattern; and
covering the other conductive film with a transparent insulating layer.

4. The method of manufacturing an input device according to claim 2,
wherein, after the forming of the insulating layer on some of the wiring conductive films, the forming of the conductive pattern and the forming of the wiring patterns on the insulating layer are sequentially performed.

5. The method of manufacturing an input device according to claim 2,
wherein, after the radiating of the laser beam onto the conductive films to form the partitioning grooves, thereby forming the wiring conductive films and the electrodes, the forming of the conductive pattern, the forming of the insulating layer on some of the wiring conductive films, and the forming of the wiring patterns on the insulating layer are sequentially performed.
